(19) United States
(12) Patent Application Publication
(10) Pub. No.: US 2024/0215353 A1
(43) Pub. Date: Jun. 27, 2024

(54) DISPLAY DEVICE AND METHOD OF MANUFACTURING THE SAME

(71) Applicant: Samsung Display Co., LTD., Yongin-si (KR)

(72) Inventor: YONGIL KIM, Yongin-si (KR)

(73) Assignee: Samsung Display Co., LTD., Yongin-si (KR)

(21) Appl. No.: 18/390,469

(22) Filed: Dec. 20, 2023

(30) Foreign Application Priority Data
Dec. 26, 2022 (KR) 10-2022-0185064

(51) Int. Cl. H10K 59/131; H10K 50/15; H10K 50/16; H10K 50/17; H10K 59/12; H10K 59/122; H10K 71/13; H10K 71/60

(52) U.S. Cl. CPC H10K 59/131; H10K 50/15; H10K 50/167; H10K 50/17; H10K 59/1201; H10K 59/122; H10K 71/135; H10K 71/60

(57) ABSTRACT

A display device includes a first electrode disposed on a substrate, a first functional layer disposed on the first electrode, a pixel defining layer disposed on the first functional layer, and a via layer disposed between the substrate and the first electrode and having liquid repellency on an upper surface overlapping the first electrode in a plan view.

### CROSS-REFERENCE TO RELATED APPLICATION(S)

This application claims priority to and the benefits of Korean Patent Application No. 10-2022-0185064 under 35 U.S.C. § 119, filed on Dec. 26, 2022, in the Korean Intellectual Property Office (KIPO), the entire contents of which are incorporated herein by reference.

### BACKGROUND

### 1. Technical Field

Embodiments relate to a display device that provides visual information and a method of manufacturing the same.

### 2. Description of the Related Art

As information technology develops, the importance of a display device as a connection medium between a user and information is being highlighted. For example, the use of display devices such as a liquid crystal display device (LCD), an organic light emitting display device (OLED), a plasma display device (PDP), a quantum dot display device or the like is increasing.

Recently, a display device including a light emitting element including an organic material has been researched. The light emitting element including a quantum dot may be formed through a printing process.

### SUMMARY

Embodiments provide a display device.

Embodiments provide a method of manufacturing the display device.

A display device according to an embodiment of the disclosure may include a first electrode disposed on a substrate, a first functional layer disposed on the first electrode, a pixel defining layer disposed on the first functional layer, and a via layer disposed between the substrate and the first electrode and having liquid repellency on an upper surface overlapping the first electrode in a plan view.

In an embodiment, the via layer may include a fluorine-based surfactant.

In an embodiment, the via layer may include a silicon-based surfactant.

In an embodiment, the first functional layer may include an inorganic metal oxide.

In an embodiment, the pixel defining layer may overlap an edge portion of the first functional layer in a plan view.

In an embodiment, the first electrode may be a cathode, and the first functional layer may be an electron transport layer.

In an embodiment, a width of the first functional layer and a width of the first electrode may be different from each other in a direction.

In an embodiment, the width of the first functional layer may be greater than the width of the first electrode in the direction.

In an embodiment, a level of an upper surface of the pixel defining layer overlapping the first functional layer in a plan view and a level of an upper surface of the pixel defining layer offset from the first functional layer in a plan view may be different from each other.

In an embodiment, a level of an upper surface of the pixel defining layer overlapping the first functional layer in a plan view may be greater than a level of an upper surface of the pixel defining layer offset from the first functional layer in a plan view.

A method of manufacturing a display device according to an embodiment of the disclosure may include forming a via layer having liquid repellency on a substrate, forming a first electrode on the via layer, forming a first functional layer on the first electrode, and forming a pixel defining layer on the first functional layer.

In an embodiment, the via layer may include a fluorine-based surfactant.

In an embodiment, the via layer may include a silicon-based surfactant.

In an embodiment, the via layer may have the liquid repellency by a carbon tetrafluoride (CF₄) plasma treatment.

In an embodiment, the first functional layer may include an inorganic metal oxide.

In an embodiment, the forming of the first functional layer may be performed by an inkjet method.

In an embodiment, the pixel defining layer may be formed to overlap an edge portion of the first functional layer in a plan view.

In an embodiment, the method of manufacturing the display device may further include reducing the liquid repellency of an upper surface of the via layer before the forming of the pixel defining layer.

In an embodiment, the reducing of the liquid repellency of the via layer may be performed by an oxygen plasma treatment.

In an embodiment, the reducing of the liquid repellency of the via layer may be performed by an ultraviolet treatment.

According to an embodiment of the disclosure, a display device may include a first electrode, a via layer, a first functional layer, and a pixel defining layer. The via layer may be disposed on the first electrode, an upper surface of the via layer overlapping the first electrode in a plan view may have liquid repellency, the first functional layer may be disposed on the via layer, and the pixel defining layer may be disposed on the first functional layer. Accordingly, a thickness uniformity of a film disposed within the opening defined by the pixel defining layer may be improved, so that a light emitting area may be increased, and as the light emitting area is increased, a display device with improved light emitting characteristics (e.g., luminous efficiency, lifetime, etc.) may be provided.

According to an embodiment of the disclosure, a method of manufacturing a display device may include forming a via layer having liquid repellency on a substrate, forming a first electrode on the via layer, forming a first functional layer on the first electrode, and forming a pixel defining layer on the first functional layer. After the forming of the first functional layer, an edge portion of the first functional layer may be covered with the pixel defining layer. Accordingly, a thickness uniformity of the film disposed within the opening defined by the pixel defining layer may be improved, so that the light emitting area may be increased, and as the light emitting area is increased, the display device with improved the light emitting characteristics (e.g., the luminous efficiency, the lifetime, etc.) may be provided.

### BRIEF DESCRIPTION OF THE DRAWINGS

FIG. 1 is a schematic cross-sectional view illustrating a display device according to an embodiment of the disclosure.

FIG. 2 is a schematic cross-sectional view illustrating a light emitting element included in the display device of FIG. 1.

FIGS. 3 to 16 are schematic cross-sectional views illustrating a method of manufacturing a display device according to an embodiment of the disclosure.

### DETAILED DESCRIPTION OF THE EMBODIMENTS

Hereinafter, embodiments will be described in more detail with reference to the accompanying drawings. The same reference numerals and/or reference characters are used for the same components in the drawings, and redundant descriptions of the same components will be omitted.

Unless otherwise specified, the illustrated embodiments are to be understood as providing exemplary features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” May refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

For the purposes of this disclosure, “at least one of A and B” May be construed as A only, B only, or any combination of A and B. Also, “at least one of X, Y, and Z” and “at least one selected from the group consisting of X, Y, and Z” May be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly. The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

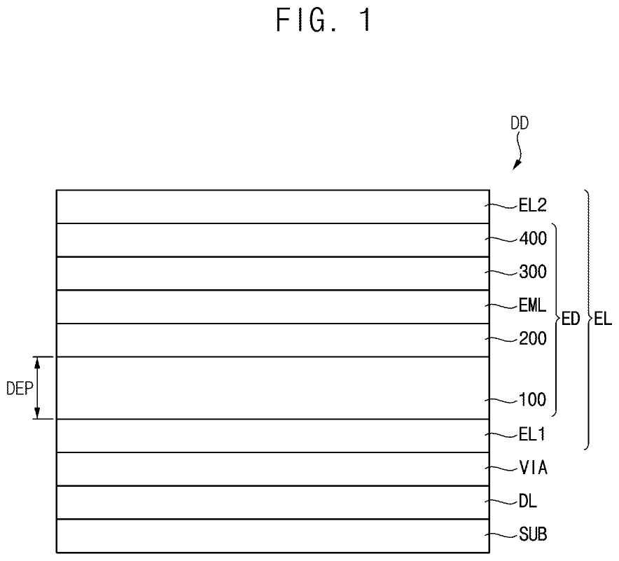

FIG. 1 is a schematic cross-sectional view illustrating a display device according to an embodiment of the disclosure.

A display device DD according to an embodiment of the disclosure may include multiple pixels. For example, each of the pixels may include a first sub-pixel, a second sub-pixel, and a third sub-pixel. The first sub-pixel may correspond to a first light emitting area. The second sub-pixel may correspond to a second light emitting area. The third sub-pixel may correspond to a third light emitting area.

Each of the first sub-pixel, second sub-pixel, and third sub-pixel may include a light emitting element ED. For example, the first sub-pixel may emit light of a first color light. The second sub-pixel may emit light of a second color light. The third sub-pixel may emit a third color light. The first color light may be red light. The second color light may be green light. The third color light may be blue light.

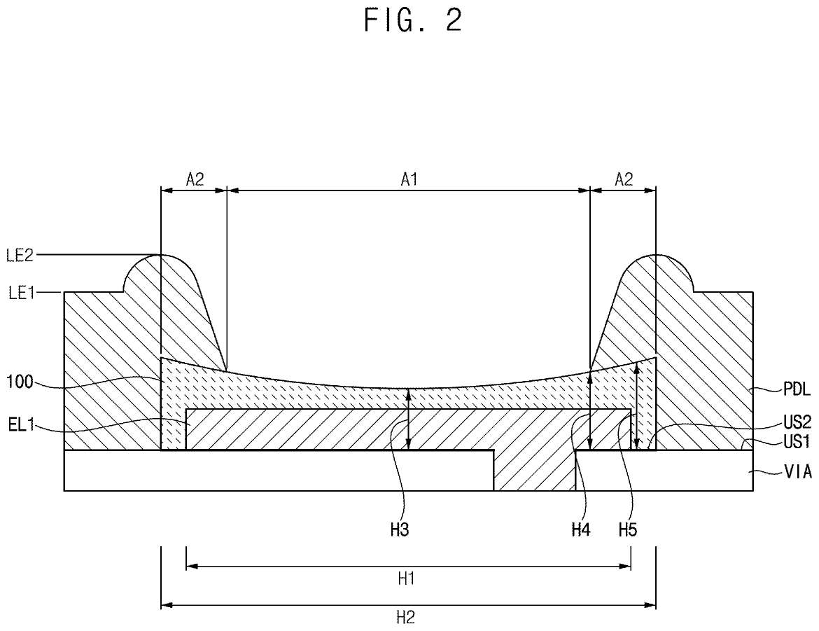

Each of the pixels may include the light emitting area (e.g., a light emitting area A1 of FIG. 2) defined by a pixel defining layer (e.g., a pixel defining layer PDL of FIG. 2). Each of the pixels may emit light having a (predetermined or selectable) peak wavelength through the light emitting area, and light generated by the light emitting element ED may be emitted through the light emitting area.

The display device DD may include a substrate SUB, a device wiring layer DL, a via layer VIA, and a light emitting element layer EL.

The substrate SUB may include a transparent or an opaque material.

For example, the substrate SUB may have a rigid property. For example, the substrate SUB having the rigid property may include a glass, a metal, the like, or a combination thereof.

For example, the substrate SUB may have a flexible property. For example, the substrate SUB having the flexible property may include polyimide (PI), the like, or a combination thereof.

The device wiring layer DL may be disposed on the substrate SUB. The device wiring layer DL may include a transistor.

The transistor may constitute a pixel circuit of each of the pixels. For example, the transistor may be a driving transistor or a switching transistor.

The transistor may include an active pattern. The active pattern may include amorphous silicon, polysilicon, a metal oxide semiconductor, or the like.

For example, the metal oxide semiconductor may include a binary compound (ABₓ), a ternary compound (ABₓC_{y}), and a quaternary compound (ABₓC_{y}D_{z}) including indium (In), zinc (Zn), gallium (Ga), tin (Sn), titanium (Ti), aluminum (Al), hafnium (Hf), zirconium (Zr), magnesium (Mg), the like, or a combination thereof.

The via layer VIA may be disposed on the device wiring layer DL. The via layer VIA may protect the device wiring layer DL.

In an embodiment, the via layer VIA may include at least one of a liquid repellent material, an organic material, and an inorganic material.

Examples of the organic material may include a photoresist, a polyacrylic-based resin, a polyimide-based resin, a polyamide-based resin, a siloxane-based resin, an acrylic-based resin, an epoxy-based resin, or the like.

Examples of the inorganic material may include silicon oxide, silicon nitride, silicon carbide, silicon oxynitride, silicon oxy-carbide, or the like.

The liquid repellent material may be a material that has a property of repelling a (predetermined or selectable) solution and does not mix well with the solution. For example, a bonding strength of the solution may be greater with a lyophilic surface than with a liquid repellent material.

Examples of the liquid repellent material may include a fluorine (F)-based surfactant, a silicon (Si)-based surfactant, the like, or a combination thereof.

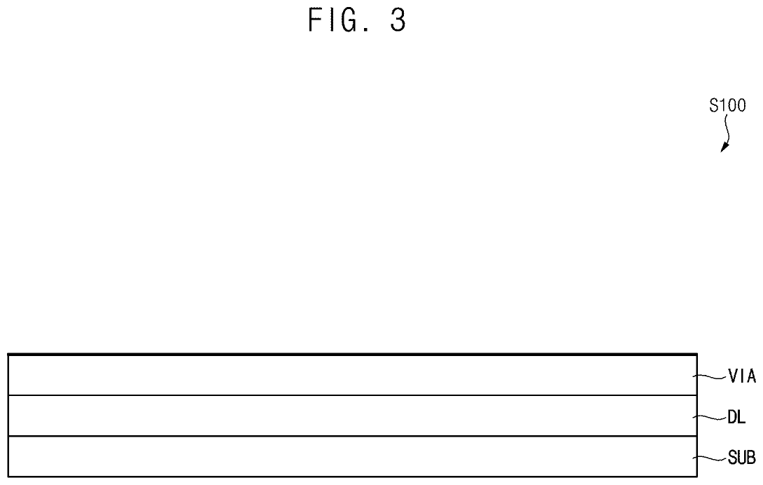

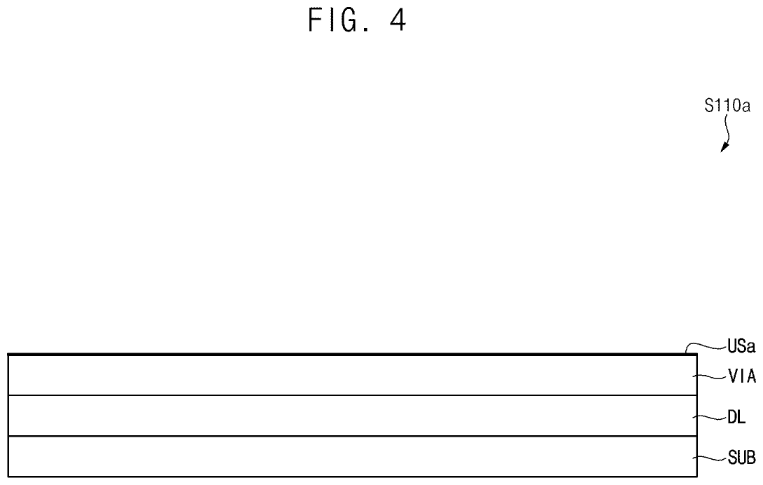

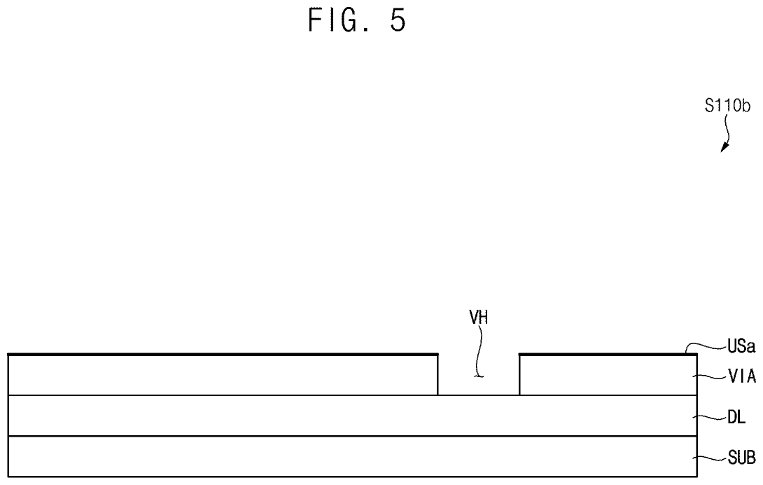

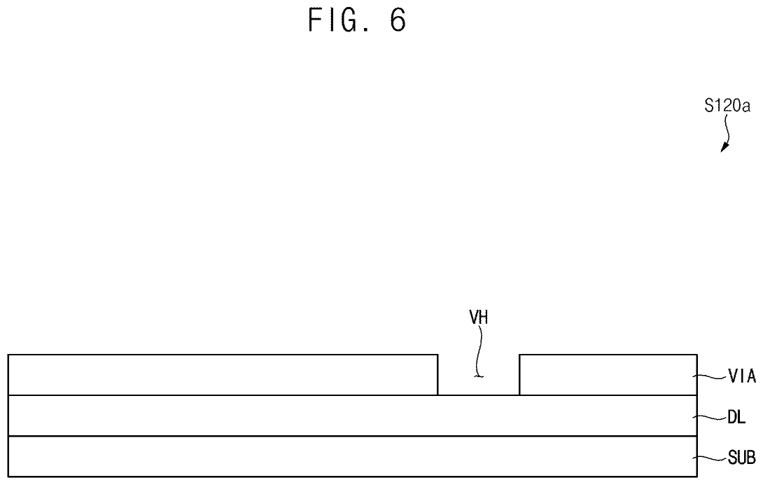

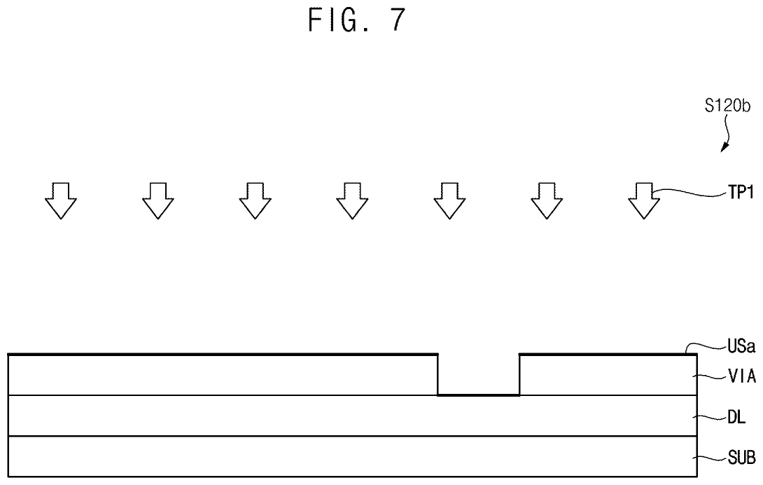

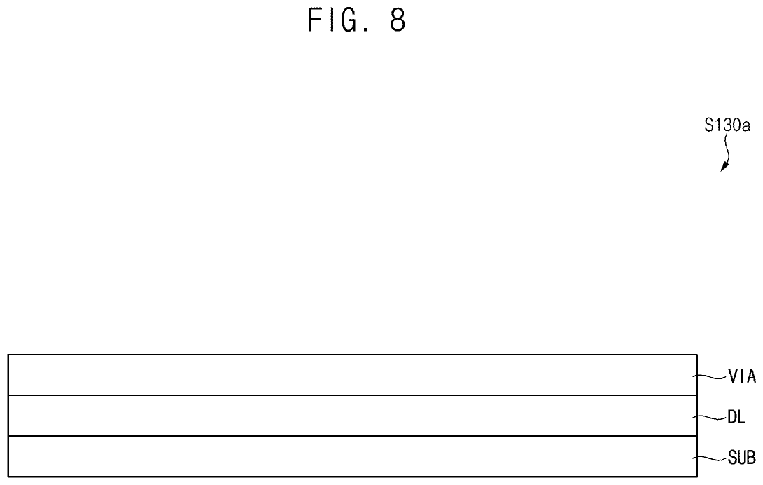

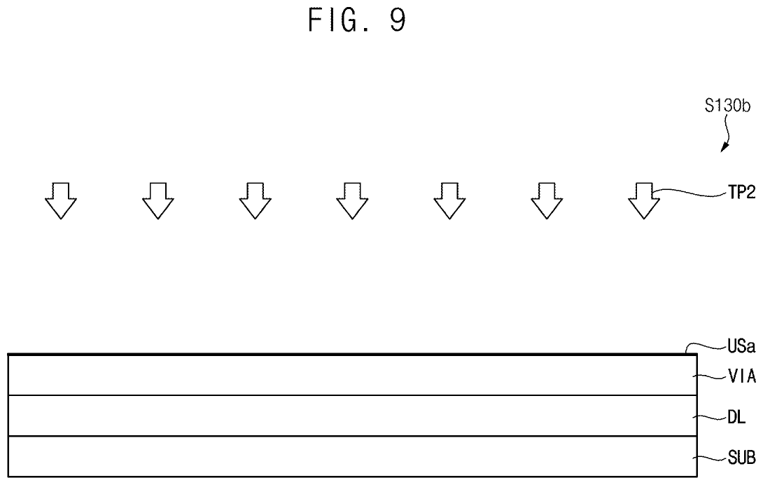

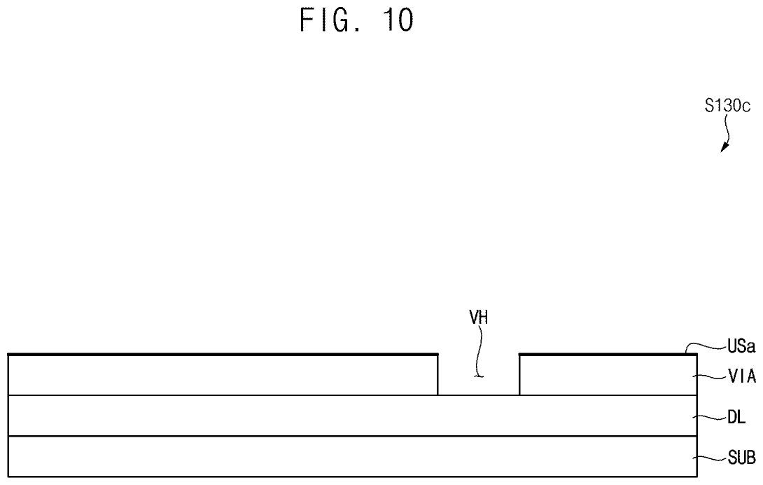

In another embodiment, an upper surface of the via layer VIA may be treated to have liquid repellency. A detailed description of a liquid repelling treatment will be described below with reference to FIGS. 3 to 10.

The light emitting element layer EL may include a first electrode EL1, the light emitting element ED, and a second electrode EL2. The light emitting element ED may include a first functional layer 100, a second functional layer 200, a light emitting layer EML, a third functional layer 300, and a fourth functional layer 400.

In an embodiment, the first electrode EL1 may be a cathode, the first functional layer 100 may be a first electron transport layer, the second functional layer 200 may be a second electron transport layer, the third function layer 300 may be a hole transport layer, the fourth functional layer 400 may be a hole injection layer, and the second electrode EL2 may be an anode.

The first electrode EL1 may be disposed on the via layer VIA. The first electrode EL1 may be disposed in each of the emission areas. The first electrode EL1 may be electrically connected to the transistor through a via hole (e.g., a via hole VH in FIG. 3) passing through the via layer VIA.

For example, the first electrode EL1 may include a metal, an alloy, a metal nitride, a conductive metal oxide, a transparent conductive material, the like, or a combination thereof.

Each of the first functional layer 100 and the second functional layer 200 may be sequentially disposed on the first electrode EL1. In an embodiment, each of the first functional layer 100 and the second functional layer 200 may be an electron transport layer.

Each of the first functional layer 100 and the second functional layer 200 may include a material having excellent electron mobility to improve characteristics (e.g., lifespan or efficiency) of the light emitting element ED.

In an embodiment, the first functional layer 100 may include an inorganic metal oxide. For example, the inorganic metal oxide may be MₓO_{y}. M may be Titanium (Ti), Zirconium (Zr), Tin (Sn), Tungsten (W), Tantalum (Ta), Nickel (Ni), Molybdenum (Mo), Copper (Cu), the like, or a combination thereof. Each of x and y may be an integer of 1 or 5. In another embodiment, the inorganic metal oxide including Zirconium (Zr) may be Zn_{(1-z)}N_{z}O. N may be a metal other than Zirconium (Zr). For example, N may be Magnesium (Mg), Cobalt (Co), Nickel (Ni), Zinc (Zn), Manganese (Mn), Tin (Sn), Yttrium (Y), Aluminum (Al), the like, or a combination thereof. z may be a real number in a range of about 0 to about 0.5.

The light emitting layer EML may be disposed on the second functional layer 200.

In the light emitting layer EML, an electron formed in the first electrode EL1 and a hole formed in the second electrode EL2 may combine to form an exciton. The exciton may emit energy in a form of light while changing from an excited state to a ground state. For example, the light emitting layer EML may emit at least one of the red light, the green light, and the blue light.

The light emitting layer EML may include multiple quantum dots. The light emitting layer EML may be formed by mixing multiple quantum dots with a solvent, discharging the mixture onto the substrate SUB, and volatilizing the solvent. Each of the quantum dots may emit light having a wavelength.

For example, the quantum dots may include a semiconductor nanocrystal material. Examples of the semiconductor nanocrystal material may include a group IV nanocrystal, a group II-VI compound nanocrystal, a group III-V compound nanocrystal, a group IV-VI nanocrystal, the like, or a combination thereof.

For example, each of the quantum dots may have a core-shell structure. The core may include a nanocrystal, and the shell may surround the core. The shell may include a material that acts as a protective layer for maintaining semiconductor properties by preventing chemical denaturation of the core and a charging layer for imparting electrophoretic properties to the quantum dots.

The third functional layer 300 and the fourth functional layer 400 may be sequentially disposed on the light emitting layer EML. In an embodiment, the third functional layer 300 may include a material that transports holes, and the fourth functional layer 400 may include a material that provides holes. In an embodiment, the third functional layer 300 may include an organic compound, for example, TPD (N, N′-diphenyl-N, N′-bis(3-methylphenyl)-1,1′-bi-phenyl-4,4′-diamine), NPB (N, N′-di(naphthalen-1-yl)-N, N′-diphenyl-benzidine), or the like. In an embodiment, the fourth functional layer 400 may include HATCN, CuPc (cupper phthalocyanine), PEDOT (poly(3,4)-ethylenedioxythiophene), PANI (polyaniline), NPD (N, N-dinaphthyl-N, N′-diphenylbenzidine), the like, or a combination thereof.

The second electrode EL2 may be disposed on the fourth functional layer 400. For example, the second electrode EL2 may include a metal, an alloy, a metal nitride, a conductive metal oxide, a transparent conductive material, the like, or a combination thereof.

In FIG. 1, the display device DD including an inverted type of a quantum dot light emitting device has been described, however, the disclosure is not limited thereto. In another embodiment, the first electrode EL1 may be an anode, the first functional layer 100 may be a hole injection layer, the second functional layer 200 may be a hole transport layer, the third functional layer 300 may be an electron transport layer, the fourth functional layer 400 may be an electron injection layer, and the second electrode EL2 may be a cathode. In another embodiment, the functional layers 100, 200, 300, or 400 may be omitted.

FIG. 2 is a schematic cross-sectional view illustrating the light emitting element included in the display device of FIG. 1.

Referring to FIGS. 1 and 2, the upper surface of the via layer VIA may be divided into a first upper surface US1 and a second upper surface US2 surrounded by the first upper surface US1.

The first upper surface US1 of the via layer VIA may overlap the pixel defining layer PDL in a plan view. The first upper surface US1 of the via layer VIA may have a lyophilic property.

The second upper surface US2 of the via layer VIA may overlap the first electrode EL1 in a plan view. The second upper surface US2 of the via layer VIA may have liquid repellency.

In an embodiment, a width H1 of the first electrode EL1 and a width H2 of the first functional layer 100 in a direction may be different from each other in a direction (for example, in a direction the light emitting elements ED are arranged). For example, the width H1 of the first electrode EL1 may be greater than the width H2 of the first functional layer 100, and the second upper surface US2 of the via layer VIA may contact the first electrode EL1 and the first functional layer 100.

However, the disclosure is not limited thereto. The width H1 of the first electrode EL1 may be less than the width H2 of the first functional layer 100. In another embodiment, the width H1 of the first electrode EL1 and the width H2 of the first functional layer 100 may be same, and the second upper surface US2 of the via layer VIA may contact only the first electrode EL1.

The first functional layer 100 may be divided into a central portion A1 and an edge portion A2 surrounding the central portion A1.

For example, the first functional layer 100 may be formed by discharging ink in which a solvent is mixed with an organic material onto the first electrode EL1 and evaporating the solvent from the ink. Generally, ink may dry faster at the edge portion A2 than the central portion A1. The ink may have a property of maintaining a spherical shape due to surface tension. The ink may flow from the central portion to the edge portion by capillary flow. The organic material moved together with the solvent may accumulate at the edge portion A2. For example, due to a coffee ring effect, a thickness H5 of the edge portion A2 of the first functional layer 100 may be greater than a thickness H4 of the first functional layer 100 between the edge portion A2 and the central portion A1 in a thickness direction of the display device DD. The thickness H4 of the first functional layer 100 between the edge portion A2 and the central portion A1 may be greater than a thickness H3 of the central portion A1 of the first functional layer 100 in the thickness direction of the display device DD.

In an embodiment, a thickness DEP of the first functional layer 100 may be the greatest among thicknesses of other layers constituting the light emitting element ED. Accordingly, a difference in thickness between the central portion A1 and the edge portion A2 of the first functional layer 100 may be greater than a difference in thickness between the central portion of the other layers constituting the light emitting element ED and the edge portion of the other layers constituting the light emitting element ED. Accordingly, a thickness uniformity of the first functional layer 100 may have the greatest effect on light emitting characteristics (e.g., luminous efficiency, lifespan, etc.) of the display device DD.

In order to improve the light emitting characteristics of the display device DD, the display device DD may include the pixel defining layer PDL overlapping the edge portion A2 of the first functional layer 100 in a plan view. The thickness H5 of the edge portion A2 of the first functional layer 100 may be much greater than the thickness H3 of the central portion A1 of the first functional layer 100. Since the display device DD includes the pixel defining layer PDL overlapping the edge portion A2 of the first functional layer 100, film thickness uniformity of the central portion A1 of the first functional layer 100 may be improved. Accordingly, a light emitting area of the display device DD may be increased. As a light emitting area increases, the display device having improved the light emitting characteristics (e.g., the luminous efficiency, the lifespan, etc.) may be provided.

The pixel defining layer PDL may overlap the edge portion A2 of the first functional layer 100 in a plan view and expose a portion (i.e., the central portion A1) of the upper surface of the first functional layer 100.

The pixel defining layer PDL may include an organic material or an inorganic material. For example, the pixel defining layer PDL may include a photoresist, a polyacrylic resin, a polyimide resin, a polyamide resin, a siloxane resin, an acrylic resin, an epoxy resin, the like, or a combination thereof.

In an embodiment, a level (or height) LE2 of the upper surface of the pixel defining layer PDL overlapping the first functional layer 100 in a plan view may be different from a level (or height) LE1 of the upper surface of the pixel defining layer PDL offset from the first functional layer 100 in a plan view. For example, the level LE2 of the upper surface of the pixel defining layer PDL overlapping the first functional layer 100 may be higher than the level LE1 of the upper surface of the pixel defining layer PDL offset from the first functional layer 100.

However, the disclosure is not limited thereto. The level LE2 of the upper surface of the pixel defining layer PDL overlapping the first functional layer 100 and the level LE1 of the upper surface of the pixel defining layer PDL offset from the first functional layer 100 may be the same. In another embodiment, the level LE2 of the upper surface of the pixel defining layer PDL overlapping the first functional layer 100 may be lower than the level LE1 of the upper surface of the pixel defining layer PDL offset from the first functional layer 100.

FIGS. 3 to 16 are schematic cross-sectional views illustrating a method of manufacturing a display device according to an embodiment of the disclosure. Hereinafter, descriptions overlapping with descriptions of the display device DD with reference to FIGS. 1 and 2 will be omitted or simplified.

Referring to FIGS. 3 to 10, after forming the device wiring layer DL on the substrate SUB, the via layer VIA may be formed on the device wiring layer DL (S100).

In an embodiment, the via layer VIA may be formed of a liquid repellent material (S110a). For example, a material including a fluorine (F)-based surfactant may be coated on the device wiring layer DL. During a baking process is performed, fluorine (F) groups may be aggregated on a surface of the via layer VIA. Accordingly, the surface of the via layer VIA may have liquid repellency. However, the disclosure is not limited thereto. The via layer VIA may be formed of various liquid repellent materials. For example, the via layer VIA may be formed by coating a material including a silicon (Si)-based surfactant on the device wiring layer DL.

The via hole VH passing through the via layer VIA may be formed (S110b). Through this, the via hole VH and the via layer VIA including an upper surface USa having liquid repellency may be formed.

In another embodiment, the via layer VIA may be formed of a material having a lyophilic property (S120a). For example, the via layer VIA may be formed of a photoresist, a polyacrylic-based resin, a polyimide-based resin, a polyamide-based resin, a siloxane-based resin, an acrylic-based resin, an epoxy-based resin, a silicon oxide, a silicon nitride, a silicon carbide, a silicon oxynitride, a silicon oxy-carbide, or the like.

A liquid repelling treatment TP1 may be performed on the upper surface USa of the via layer VIA (S120b).

In an embodiment, the via layer VIA may have liquid repellency by a carbon tetrafluoride (CF4) plasma treatment. However, the disclosure is not limited thereto, and the liquid repelling treatment TP1 is not limited as long as the upper surface USa of the via layer VIA has liquid repellency and conductivity.

In another embodiment, the via layer VIA may be formed (S130a), a liquid repelling treatment TP2 may be performed on the via layer VIA (S130b), and the via hole VH may be formed (S130c).

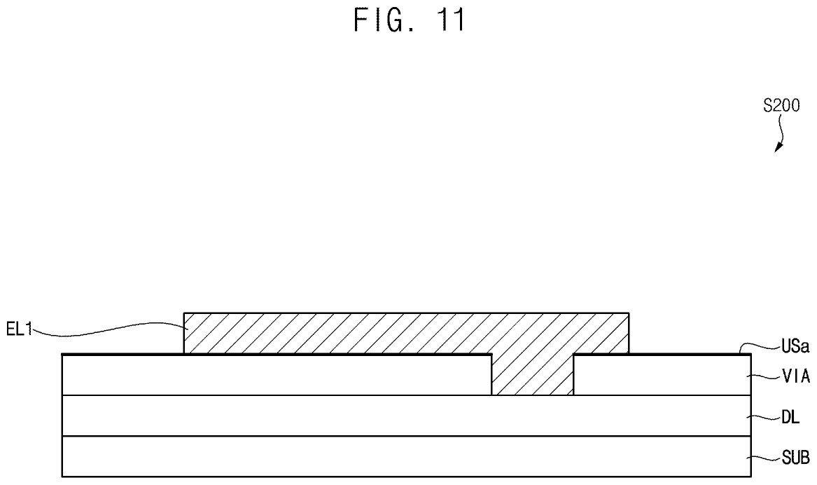

Referring to FIG. 11, the first electrode EL1 may be formed on the via layer VIA (S200).

For example, the first electrode EL1 may be formed of a metal, an alloy, a metal nitride, a conductive metal oxide, a transparent conductive material, or the like.

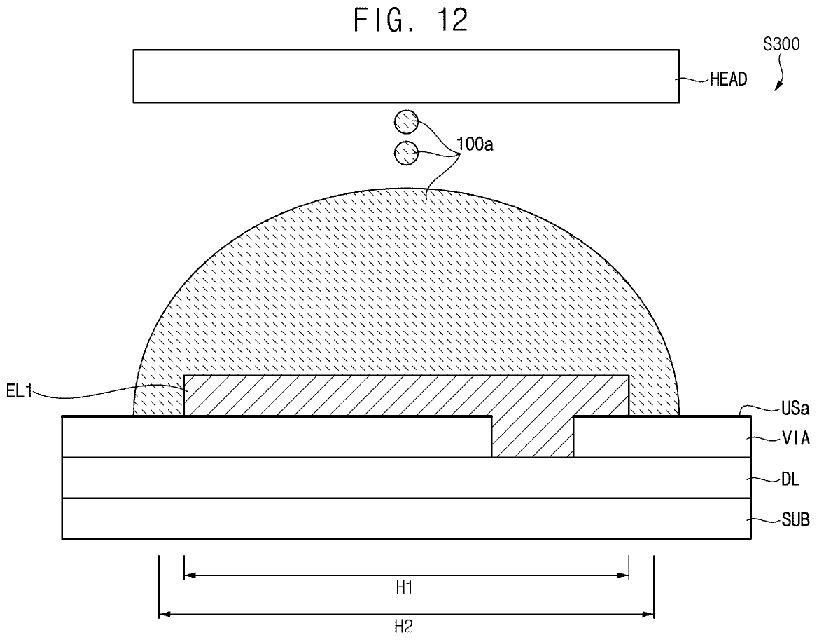

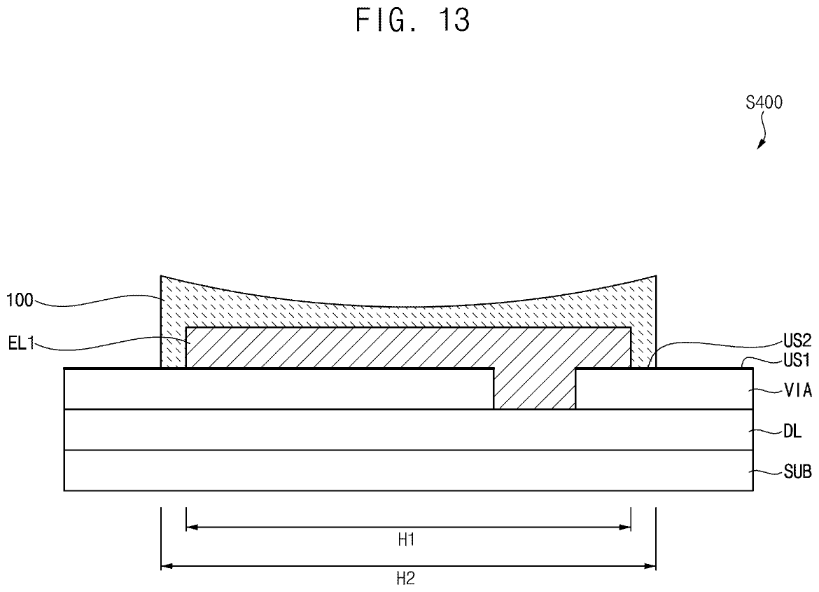

Referring to FIGS. 12 and 13, the first functional layer 100 may be formed on the first electrode EL1 (S300 and S400).

In an embodiment, the first functional layer 100 may be formed by an inkjet method. The inkjet method may include a printing step, a drying step, and a baking step. The printing step may include discharging of ink 100a on the via layer VIA. Since the upper surface USa of the via layer VIA has liquid repellency, the ink 100a discharged from a head HEAD may not spread and may be aggregated. After the drying step and the baking step, the first functional layer 100 may be formed.

In an embodiment, the width H1 of the first electrode EL1 and the width H2 of the first functional layer 100 may be different from each other in a direction. The ink 100a may flow from an upper surface of the first electrode EL1 and may contact the upper surface USa of the via layer VIA. The width H1 of the first electrode EL1 may be greater than the width H2 of the first functional layer 100. However, the disclosure is not limited thereto. For example, in case that a cohesive force of the ink 100a is strong, the width H1 of the first electrode EL1 may be greater than a width of the first functional layer 100. In another embodiment, the width H1 of the first electrode EL1 and the width of the first functional layer 100 may be same.

In an embodiment, the first functional layer 100 may be formed of an inorganic metal oxide. For example, the inorganic metal oxide may be MₓO_{y}. M may be Titanium (Ti), Zirconium (Zr), Tin (Sn), Tungsten (W), Tantalum (Ta), Nickel (Ni), Molybdenum (Mo), Copper (Cu), the like, or a combination thereof. Each of x and y may be an integer of 1 or 5. In another embodiment, the inorganic metal oxide including Zirconium (Zr) may be Zn_{(1-z)}N_{z}O. N may be a metal other than Zirconium (Zr). For example, N may be Magnesium (Mg), Cobalt (Co), Nickel (Ni), Zinc (Zn), Manganese (Mn), Tin (Sn), Yttrium (Y), Aluminum (Al), the like, or a combination thereof. z may be a real number in a range of about 0 to about 0.5.

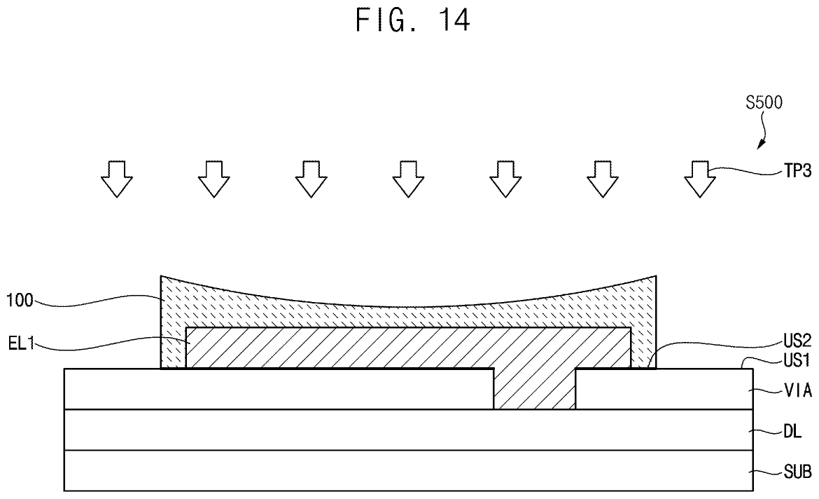

Referring to FIG. 14, a lyophilic treatment TP3 may be performed on the first upper surface US1 of the via layer VIA that does not overlap the first functional layer 100 (S500) in a plan view. The lyophilic treatment TP3 may reduce the liquid repellency of the first upper surface US1 of the via layer VIA.

In an embodiment, the liquid repellency of the via layer VIA may be reduced by an oxygen plasma treatment.

In another embodiment, the liquid repellency of the via layer VIA may be reduced by an ultraviolet (UV) treatment.

Accordingly, the first upper surface US1 of the via layer VIA offset from the first functional layer 100 in a plan view may have a lyophilic property, and the second upper surface US2 of the via layer VIA overlapping the first electrode EL1 in a plan view may have liquid repellency.

However, the disclosure is not limited thereto, and the lyophilic treatment TP3 is not limited as long as it is a method capable of the reducing of the liquid repellency of the first upper surface US1 of the via layer VIA.

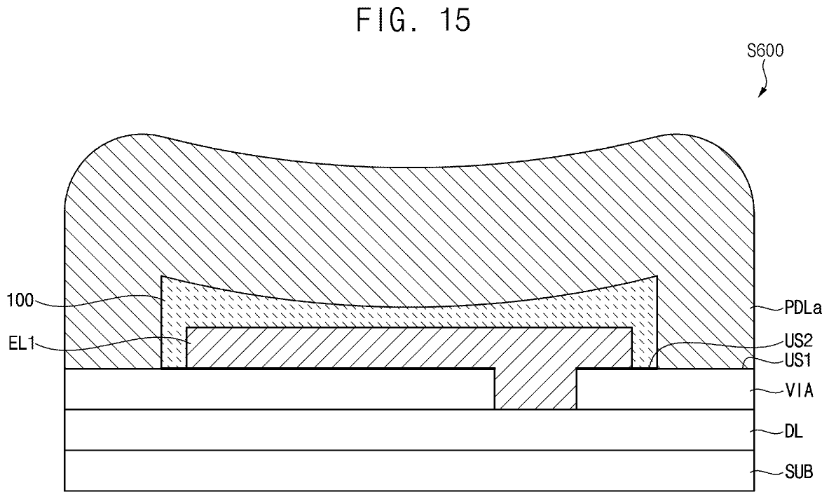

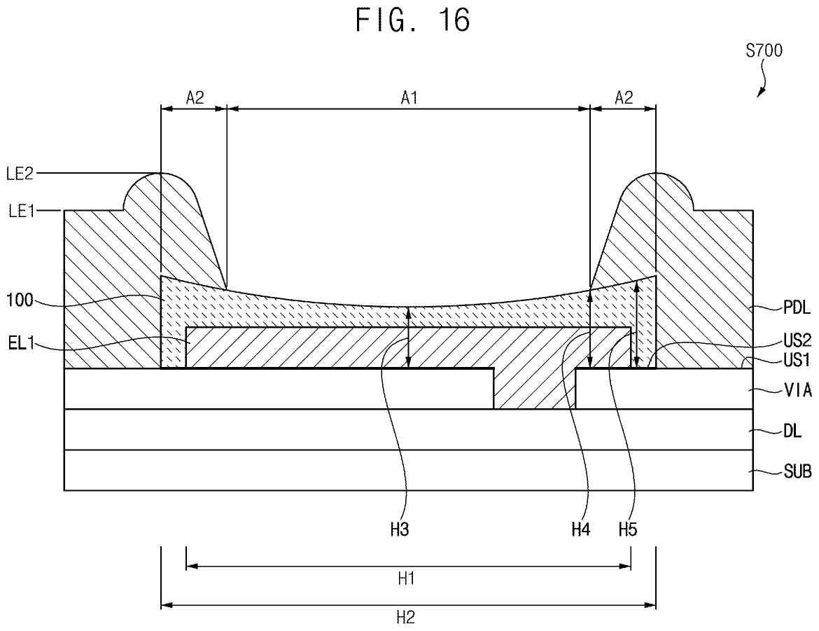

Referring to FIGS. 15 and 16, the pixel defining layer PDL may be formed on the first functional layer 100 and the via layer VIA (S600 and S700).

A preliminary pixel defining layer PDLa may be formed on the first functional layer 100 and the via layer VIA. A portion of the preliminary pixel defining layer PDLa overlapping the central portion A1 of the first functional layer 100 in a plan view may be removed. Accordingly, the pixel defining layer PDL may be formed to overlap the edge portion A2 of the first functional layer 100 in a plan view.

Due to the coffee ring effect, the thickness H5 of the edge portion A2 of the first functional layer 100 may be greater than the thickness H4 of the first functional layer 100 between the edge portion A2 and the central portion A1. The thickness H4 of the first functional layer 100 between the edge portion A2 and the central portion A1 may be greater than the thickness H3 of the central portion A1. As the thickness difference increases, the light emitting area of the display device DD may decrease, and a resonance thickness may not be satisfied. In case that the first functional layer 100 is an electron transport layer, the electron may not be readily transferred to the light emitting layer (e.g., the light emitting layer EML of FIG. 1).

In order to improve the light emitting characteristics of the display device DD, the pixel defining layer PDL may be formed to overlap the edge portion A2 of the first functional layer 100 in a plan view. The thickness H5 of the edge portion A2 of the first functional layer 100 may be greater than the thickness H3 of the central portion A1 of the first functional layer 100. By forming the pixel defining layer PDL to overlap the edge portion A2 of the first functional layer 100, the film thickness uniformity of the central portion A1 of the first functional layer 100 may be improved. Accordingly, the light emitting area of the display device DD may be increased. As the light emitting area increases, the display device having improved the light emitting characteristics (e.g., the luminous efficiency, the lifespan, etc.) may be manufactured.

The embodiments of the disclosure may be applied to various display devices. For example, the disclosure may be applied to a high-resolution smartphone, a mobile phone, a smart pad, a smart watch, a tablet PC, a vehicle navigation system, a television, a computer monitor, a laptops, or the like.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first electrode disposed on a substrate;
a first functional layer disposed on the first electrode;
a pixel defining layer disposed on the first functional layer; and
a via layer disposed between the substrate and the first electrode and having liquid repellency on an upper surface overlapping the first electrode in a plan view.

2. The display device of claim 1, wherein the via layer comprises a fluorine-based surfactant.

3. The display device of claim 1, wherein the via layer comprises a silicon-based surfactant.

4. The display device of claim 1, wherein the first functional layer comprises an inorganic metal oxide.

5. The display device of claim 1, wherein the pixel defining layer overlaps an edge portion of the first functional layer in a plan view.

6. The display device of claim 1, wherein
the first electrode is a cathode, and
the first functional layer is an electron transport layer.

7. The display device of claim 1, wherein a width of the first functional layer and a width of the first electrode are different from each other in a direction.

8. The display device of claim 7, wherein the width of the first functional layer is greater than the width of the first electrode in the direction.

9. The display device of claim 1, wherein a level of an upper surface of the pixel defining layer overlapping the first functional layer in a plan view and a level of an upper surface of the pixel defining layer offset from the first functional layer in a plan view are different from each other.

10. The display device of claim 1, wherein a level of an upper surface of the pixel defining layer overlapping the first functional layer in a plan view is greater than a level of an upper surface of the pixel defining layer offset from the first functional layer in a plan view.

11. A method of manufacturing a display device, the method comprising:
Forming a via layer having liquid repellency on a substrate;
forming a first electrode on the via layer;
forming a first functional layer on the first electrode; and
forming a pixel defining layer on the first functional layer.

12. The method of claim 11, wherein the via layer comprises a fluorine-based surfactant.

13. The method of claim 11, wherein the via layer comprises a silicon-based surfactant.

14. The method of claim 11, wherein the via layer has the liquid repellency by a carbon tetrafluoride (CF₄) plasma treatment.

15. The method of claim 11, wherein the first functional layer comprises an inorganic metal oxide.

16. The method of claim 15, wherein the forming of the first functional layer is performed by an inkjet method.

17. The method of claim 11, wherein the pixel defining layer is formed to overlap an edge portion of the first functional layer in a plan view.

18. The method of claim 11, further comprising:
reducing the liquid repellency of an upper surface of the via layer before the forming of the pixel defining layer.

19. The method of claim 18, wherein the reducing of the liquid repellency of the via layer is performed by an oxygen plasma treatment.

20. The method of claim 18, wherein the reducing of the liquid repellency of the via layer is performed by an ultraviolet treatment.
